(19) United States
(12) Patent Application Publication
(10) Pub. No.: US 2008/0197469 A1
(43) Pub. Date: Aug. 21, 2008

(54) Multi-chips package with reduced structure and method for forming the same

(75) Inventors: Wen-Kun Yang, Hsin-Chu City (TW); Hsien-Wen Hsu, Lujhou City (TW); Ya-Tzu Wu, Bade City (TW); Ching-Shun Huang, Chigtong Township (TW)

Correspondence Address: BACON & THOMAS, PLLC, 625 SLATERS LANE, FOURTH FLOOR, ALEXANDRIA, VA, 22314, US

(73) Assignee: Advanced Chip Engineering Technology Inc., Hukou Township (TW)

(21) Appl. No.: 11/708,475

(22) Filed: Feb. 21, 2007

(51) Int. Cl. H01L 23/48; H01L 21/00

(52) U.S. Cl. 257/686; 438/118; 257/E23.01; 257/E21.001

(57) ABSTRACT

The present invention provides a structure of multi-chips package and Method of the same comprising a substrate with a pre-formed die receiving cavity formed within an upper surface of the substrate. A die is disposed within the die receiving cavity by adhesion and an elastic dielectric layer filled into a gap between the die and the substrate to absorb thermal mechanical stress; therefore the thickness of the package is reduced and the CTE mismatch of the structure is reduced. The present invention also provides a structure for SIP with higher reliability and lower manufacturing cost. the process is simpler and it is easy to form the multi-chips package than the traditional one. Therefore, the present invention discloses a fan-out WLP with reduced thickness and good CTE matching performance.

### FIELD OF THE INVENTION

The present invention relates to a structure for system in Package (SIP), and more particularly to a panel scale package (PSP) with SIP.

### DESCRIPTION OF THE PRIOR ART

In the field of semiconductor devices, the device density is increased but the device dimension is reduced. the traditional package technique, for example lead frame package, flex package, rigid package technique, can't meet the demand of producing smaller chip with high density elements on the chip; therefore, new packaging or interconnecting techniques for such high density devices become demanding.

For the reasons mentioned above, the trend of package technique development is toward ball grid array (BGA), flip chip (FC-BGA), chip scale package (CSP), Wafer level package (WLP); wherein, WLP technique is an advanced packaging technology, by which the dice are packaged and tested on the wafer before performing singulating. Furthermore, WLP is such an advanced technique so that the process of wire bonding, die mount and under-fill can be omitted. By utilizing WLP technique, the cost and manufacturing time can be reduced, and the resulting structure of WLP can be nearly equal to the die; therefore, this technique meets the demands of miniaturization of electronic devices.

Although utilizing WLP technique can also reduce the CTE mismatch between IC and the interconnecting substrate (for example the CTE mismatch between build up layers and a RDL), the CTE difference between that of silicon chips (2.3) and that of core paste (20-180) is still large that the resulting mechanical stress causes reliability problem during TCT process. Furthermore, different composition materials, for example, core paste, glass and epoxy, on scribe line would complicate sawing process.

Another aspect of the traditional WLP process need to be refined is that all of the stacked redistribution layers are formed over the built-up layer over the die; therefore, the thickness of the package needs further reduced to meet the demand of reducing the size of a packaging structure.

Therefore, the present invention provides a multi-chips package for fan-out WLP (panel wafer) with reduced stack height and lower CTE mismatch.

### SUMMARY OF THE INVENTION

One advantage of the present invention is providing a structure for SIP with higher reliability and lower manufacturing cost.

One advantage of the present invention is providing a manufacturing process is simpler and easier for forming the multi-chips package than the traditional method.

Another advantage of the present invention is to provide a structure of multi-chips package and method of the same for avoiding die shift issue during manufacturing process.

Still another advantage of the present invention is to provide a structure of multi-chips package and method of the same without injecting mold tool during manufacturing process.

Yet another advantage of the present invention is to provide a structure of multi-chips package and method of the same for avoiding warp during manufacturing process.

One advantage of the present invention is that the substrate is characterized with pre-formed cavities and the die is received within the pre-formed cavity of the substrate for reducing the thickness of the package. Further, the substrate and the die receiving cavity are pre-prepared before packaging; thus, the throughput will be improved than ever.

The structure of the present invention is formed without filling core paste; the pre-formed cavities fills with the elastic dielectric materials for absorbing the thermal mechanical stress due to the CTE difference between silicon die and substrate (organic type, preferably FR5/BT).

Another characters of the manufacturing process comprising: only dielectric layer (preferably siloxane polymers) coating on the active surface of die and the substrate (preferably FR5 or BT) surface. The dielectric layer (SINR) is photosensitive layer; therefore the opening formed thereon can be formed by photo mask process. Vacuum process is performed to eliminate the bubble for SINR coating. The die attached material is printed on the backside of dice before substrate is bonded with dice (chips).

The structure of the present invention can reach better reliability, because the CTE of the substrate and the PCB mother board are identical, which causes no thermal mechanical stress is applied on the solder bumps/balls; therefore, the structure can reach the best reliability when executing the board level temperature cycling test (TCT).

The present invention provides a structure of multi-chips package comprising a substrate with a die receiving cavity pre-formed within the substrate and metal pads on the upper surface of substrate; wherein the first die disposed within the die receiving cavity by adhesion. a dielectric layer formed on the first die and the substrate and filled into a gap between the die and the substrate to absorb thermal mechanical stress there between. A build up layer formed on the dielectric layer; wherein the build up layer comprises a re-distribution layer (RDL), an elastic dielectric layer. Several openings are formed on the upper surface of the build up layers to expose at least one of the RDL. Conductive metals are formed on the openings and electrically coupled to the first die through the RDL and the second die with metal pads set up on the conductive metals; wherein the first die and the second die keep electrical contact through the conductive metals.

The present invention provides a method for forming semiconductor device package comprising: providing a substrate with a pre-formed die receiving cavity within an upper surface of the substrate and the metal pads on the upper surface of substrate. Re-distribute the first die on a die redistribution tool with desired pitch by a pick and place fine alignment system; then, an adhesive material applied at the periphery area of the carrier tool to adhere the substrate. Attaching an adhesive material on back side of the die and then bonding the die to the cavity of the substrate; next, performing vacuum curing process to ensure the die is attached on the substrate. After finishing the proceeding steps, Separating the die redistribution tool from the substrate. Next, coating an elastic dielectric layer on the die and the substrate, and filling the elastic dielectric layer into the gap between the die and the cavity and performing vacuum procedure to eliminate bubble. The steps for forming build up layers over the surface of the die and substrate includes forming at least one RDL over the elastic dielectric layer. Forming several openings on the upper surface of the build up layers to expose at least one of the RDL. Next, forming conductive metals (UBM) on the openings and then setting up a second die with metal pads on the conductive metals.

### BRIEF DESCRIPTION OF THE DRAWINGS

FIG. 1 illustrates a cross-sectional view of a structure of fan-out SIP according to the present invention.

FIG. 2 illustrates a cross-sectional view of a structure of fan-out SIP according to the present invention.

FIG. 3 illustrates a cross-sectional view of the combination of the package attached on the PCB or Mother Board according to the present invention.

FIG. 4 illustrates a cross-sectional view of the combination of the substrate and the carrier tool according to the present invention.

FIG. 5 illustrates a top view diagram of the combination of the substrate and the carrier tool according to the present invention.

### DESCRIPTION OF THE PREFERRED EMBODIMENT

The invention will now be described in greater detail with preferred embodiments of the invention and illustrations attached. Nevertheless, it should be recognized that the preferred embodiments of the invention is only for illustrating. Besides the preferred embodiment mentioned here, present invention can be practiced in a wide range of other embodiments besides those explicitly described, and the scope of the present invention is expressly not limited expect as specified in the accompanying Claims.

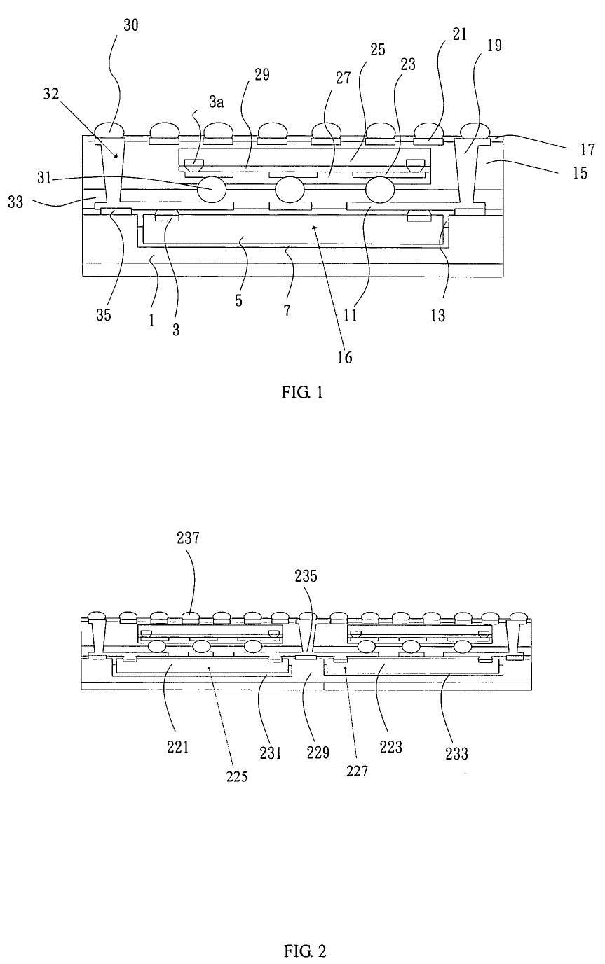

The present invention discloses a structure of Fan-out WLP having a substrate with at least a predetermined cavity and metal pads formed therein. FIG. 1 illustrates a cross-sectional view of panel scale package (PSP) for system in package (SIP) in accordance with one embodiment of the present invention. As shown in the FIG. 1, the structure of SIP includes a substrate 1 having a die receiving cavity 9 formed therein to receive at least the first die 5 with Al pads 3 (metal bonding pads) formed thereon. Preferably, the length and width of the cavity 9 should be around 100 μm longer than that of the first die 5 and the deepness of the cavity 9 should be little higher than the height of the first die 5, for example around 25-50 μm. The substrate 1 mentioned above could be round type such as wafer type, with the diameter 200, 300 mm or higher; or rectangular type such as panel or frame form. As shown in the FIG. 1, the first die 5 disposed inside the cavity 9 is fixed by an adhesion 7 (die attached materials with elasticity). A first dielectric layer A (DLA) 13 is applied to cover the top surface of the first die 5 and substrate 1 and fills the space between the first die 1 and the side walls of the cavity 9.

Several openings are formed on the DLA 13 for accommodating metal pads 35 on substrate 1; wherein openings are formed by the lithography process or exposure and development procedure. Metal pads 35 connect to the first re-distribution layer (RDL) 29 and keep electrical connect with Al pads 3.

Then a dielectric layer B (DLB) 33 is formed atop to cover the first RDL 11 and the DLA 13; wherein a plurality of openings are formed on the DLB 33 for exposing portion of first RDL 11 for placing conductive metal 31.

To sum up, because the first chip 5 is formed within a cavity 9, the height of the entire SIP is reduced accordingly. Furthermore, the first RDL configuration is Fan-Out type; therefore the ball pitch is increased and thereby the reliability and thermal dispassion condition is also improved.

A Dielectric layer 29 is formed (coated) under a surface of a second die 25 with second pads 3a formed thereon. A second RDL 23 is formed under the dielectric layer 29 and connected to the die pads 3a. A dielectric material 27 with certain open through holes is formed (coated) over the second RDL 23; wherein these open through holes are used for accommodating the conductive metal 31; therefore the conductive metal 31 can keep electrical contact with the second RDL 23.

As shown in the FIG. 1, the second die 25 stack on the first die 5 by flip chip and keep electrical contact through the conduct metal 31, the first RDL 11, the second RDL 23, the Al pads 3 and the second pads 3a; wherein pads of the two dice are placed oppositely.

Core paste 15 is applied around the second die 25 and fills the space between the second die 25 and the other component, for example, conductive metal 31; wherein the material of core paste 15 could be epoxy, rubber, and resin, plastic, ceramic and so on. As shown in the FIG. 1, several open through holes 32 and cavities are formed on the core paste 15 for forming the third RDL, wherein the open through holes 32 are used for the first die 5 and the second die 25 to keep electrical contact with outside. For example the pads 21 and the conductive metal 19 formed in open through holes 32 are used for the first die 5 and the second die 25 to keep electrical contact with outside. A dielectric layer (photo type) is formed on the core paste 15; wherein several openings are formed on the pads 21; in another embodiment, contact metals 30 is formed on the pads 21 (as UBM structure).

After describing the structural character of one embodiment of the present invention, the paragraph below relates to the material used in the embodiment of the present invention. Preferably, the material of the pre-formed substrate 1 is a kind of organic substrate which is easy for forming die receiving cavity and placing a metal pads on the surface; wherein the substrate 1 comprises at least two laminated layers, for example, copper-clad laminate (CCL): one has die receiving holes formed therein and another one is placed at the bottom of substrate 1. Preferably a material for forming substrate 1 is a kind of material with Glass transition temperature (Tg)>170° C. and with the CTE value around 16 in X direction or Y direction and around 60 in Z direction, for example, FR5 or BT (Bismaleimide triazine). In one embodiment of the present invention, the dielectric layer 13 is preferably an elastic dielectric material which is made by silicone dielectric based materials comprising siloxane polymers (SINR), Dow Corning WL5000 series, and composites thereof. For releasing thermal mechanical stress. In another embodiment, the dielectric layer is made by a material comprising polyimides (PI) or silicone resin; preferably, the dielectric layer is a photosensitive layer for simple process. In another embodiment of the present invention, the elastic dielectric layer 13 is a kind of material with CTE larger than 100 (ppm/° C.), elongation rate about 40 percent (preferably 30 percent-50 percent), and the hardness of the material is between plastic and rubber. The thickness of the elastic dielectric layer 13 depends on the stress accumulated in the RDL/dielectric layer interface during temperature cycling test.

In one embodiment of the invention, the material of the RDL comprises Ti/Cu/Au alloy or Ti/Cu/Ni/Au alloy and the thickness of the RDL is between 2 μm and 15 μm. The Ti/Cu alloy is formed by sputtering technique and the Cu/Au or Cu/Ni/Au alloy is formed by electro-plating; wherein exploiting the electro-plating process to form the RDL can make the RDL thick enough to withstand CTE mismatching between the die and the substrate during temperature cycling. In another embodiment, Ti/Cu alloy also can work as seed metal layer. The metal pads 3, 3a can be Al or Cu or combination thereof. In another embodiment, the structure of FO-WLP utilizes siloxane polymers (SINR) as the elastic dielectric layer and Cu as the RDL metal for reducing the stress accumulated in the RDL/dielectric layer interface.

The FIG. 2 illustrates a packaging structure installed with side by side form and stacking form. The first die 221 and the second die 223 (the lower dice illustrated in FIG. 2) are disposed within the die receiving cavities 225, 227 with the desired size on the substrate 229 and fixed by an adhesion (die attached) material 231 and 233, respectively. In another embodiment, the die receiving cavities 225 and 227 can be formed with different size. The second die 223 is located adjacent to the first die 221 and both dice are communicated with each other via a horizontal communication line 235. The third die 241 and the fourth die 243 (the upper dice illustrated in FIG. 2) with flip chip bumps structure, which comprises the second RDL and metal pads, are attached on the surface of the first die 221 and the second die 223. The multi chips mentioned above keep electrical connection through the metal bumps, RDL and through holes to final conductive bumps (metal) 237. The BGA with conductive bumps 237 are shown in the illustration; if the conductive bumps are omitted, it refers to LGA type SIP (system in package) or SIP-LGA.

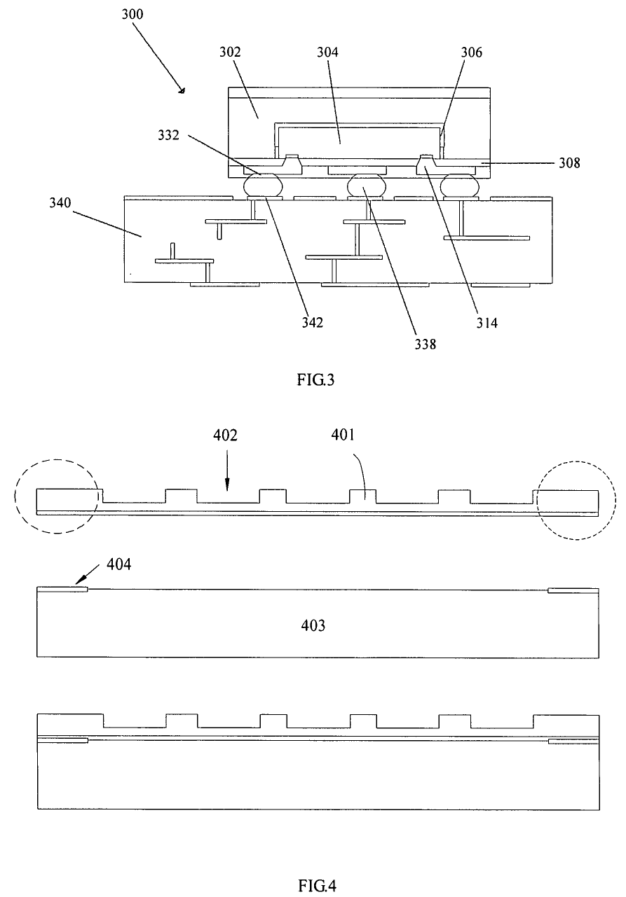

FIG. 3 illustrates a cross-section view diagram of the combination of the package 300 attached on the PCB or Mother Board 340 by soldering join for explaining the reliability improvement of the structure of the present invention during board level temperature cycling test. The silicon die 304 (CTE is 2.3) is packaged inside the package; wherein FR5 or BT organic epoxy type material (CTE is approximately 16) with the same CTE value as that of PCB or Mother Board 340 is employed as the substrate 302. The gap between the die 304 and the substrate 302 is filled with elastic materials 306 to absorb the thermal and mechanical stress due to CTE mismatching between die and the substrate (FR5/BT). The Dielectric layers 308 is also an elastic material, therefore, the stress between the die pads 338 and the PCB 340 can be absorbed too.

The RDL metal 314 is made by Cu/Au materials (CTE is around 16) and the CTE value of the RDL metal 314 is the same as that of PCB 340 and organic substrate 302. The UBM 332 of contact bump 338 is located on the terminal contact metal pads of substrate 302. The metal land of PCB 342 is made by Cu (CTE is around 16) and the CTE value of the metal land of PCB 342 is the same as that of PCB 340. Therefore, from the description above, the present invention provides better reliability (no thermal stress in X/Y direction-on board) and the Z direction stress is also absorbed by the elastic DL; furthermore, only one material (Epoxy type) is involves the singulation.

According to the aspect of the present invention, the present invention further provides a method for forming a semiconductor device package. The steps are illustrated below.

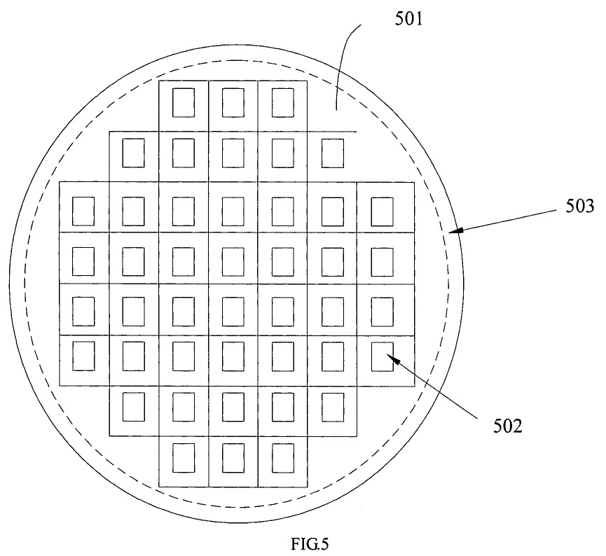

As shown in FIG. 4 there is a substrate 401 with die receiving cavity 402. It should be noted that there is no die cavity formed at the edge of the substrate 401, because the edge of the substrate 401 is for stick the substrate 401 on a glass carrier 403 during WLP process. Therefore, as shown in the FIG. 4, an adhesive material 404 (preferably UV curing type) is applied on the edge of the glass carrier tool 403 (the size is the same as the substrate 401) for sticking the substrate 401 on the glass carrier tool 403, wherein the materials of carrier tool are glass, silicon, ceramic, alloy 42 or PCB, preferably, the adhesive material 404 is the same as that used for die redistribution tool, substrate and the carrier tool for reducing die shift during process. At last, the glass carrier tool 403 and the substrate 401 are combined as shown in FIG. 4 after finishing bonding and UV curing.

FIG. 5 illustrate that the top view of the substrate 501, as shown in the figure, there is no die cavity 502 formed at the edge of the substrate 501 and the periphery area 503 is for sticking and holding the substrate 501 on the glass carrier during WLP process. After the WLP process is completed, cutting the area indicated by the dot line the glass carrier, and performing the sawing process on the inner area defined by the dot line for package singulation.

The paragraph below describes the manufacturing process of the structure of the present invention; wherein the present invention includes providing a die redistribution tool with alignment pattern and patterned glues formed thereon.

First, the substrate with die receiving cavities and the metal pads on the surface formed therein is pre-formed; preferably, the substrate is made of material with higher Glass transition temperature (Tg), for example FR5/BT, and the depth of the cavities is 20 um to 50 um deeper than the thickness of dice for accommodating die attached material. In another embodiment, the substrate may have cavities with different size to receive different chips.

A die redistribution tool (plate) with alignment pattern formed thereon is provided and the pattern glues is printed on the tool for sticking the surface of dice; then using pick and place alignment system designed for flip chip to re-distribute the first die on the tool with desired pitch. Subsequently, the die attached materials is printed on the back side of the die. In another embodiment, the vacuum panel bonder is used to bond the back side of the die on the substrate. Curing to the die attached material to ensure the die is attached on the substrate, and then separating the tool with panel wafer (Panel wafer means the die be attached on the cavity of substrate).

Alternatively, the die bonder machine with fine alignment can be employed, and a die attached materials is dispensed on the cavity surface for fixing the die or the die with attached tape on the back side is utilized. The die is placed onto the cavity of substrate, and then the die attached materials is thermally cured to ensure the die is attached on the substrate.

Once the die is re-distributed on the substrate, then the process for the first build up layer is initiated. A clean up procedure is performed to clean the dice surface by wet and/or dry clean, and then coating the dielectric materials on the panel surface. In the following step, performing vacuum procedure to ensure that there is no bubble within the panel. Subsequently, lithography process is performed for forming openings for metal via, metal (Al) bonding pads and/or scribe line. Then, the Plasma clean step is performed for cleaning the surface of openings (for contact metal pads) and metal (Al) bonding pads. Next, Ti/Cu is sputtered as seed metal layers, followed by coating Photo Resistor (PR) over the dielectric layer and seed metal layers to form the patterned redistributed metal layers (RDL).

The electro plating is processed to form a layer of Cu/Au or Cu/Ni/Au as the RDL metal; then stripping the PR and performing wet etching to form the RDL metal trace. Subsequently, next steps are to coat or print the top dielectric layer and then forming the openings for the contact metal pads of solder bump and/or the scribe line by photo mask process, thereby completing the first layer panel process.

The following process is for forming the second build up layer on the upper die, including introducing a wafer level packaging process for forming the second build up layers with the solder bumps structure, and dicing saw the wafer (processed) into individual flip chip die. The upper die is placed on the first build up layer by flip chip attachment, and then performing the IR re-flow to solder join for fixing the die on the panel. Vacuum printing core paste on the dielectric layer and the upper die is employed to eliminate the bubble issue. Next step is to perform photo mask process or laser drill to form openings for the contact through holes and Al pads of the die and then cleaning the through holes by plasma.

In Next step, sputtering Ti/Cu as seed metal layers is introduced, and then coating photo resistor (PR) over the dielectric layer and seed metal layers for forming the patterned redistributed metal layers (RDL). Subsequently, the next step is to coat or print the top dielectric layer and then forming the openings for scribe line, and opening the ball metal pads by photo mask process or laser drill process. The next procedure could be repeated the above mentioned steps, for example performing sputtering Ti/Cu step to form the seed metal layers, coating PR to form the patterned RDL, electro plating step for forming Cu/Au into patterned RDL, stripping the PR and wet etching seed metal to form second RDL metal trace to form UBM structure if it is needed.

After the ball placement or solder paste printing, the heat re-flow procedure is performed to re-flow on the substrate side (for BGA type). The testing is executed. Panel wafer level final testing is performed by using vertical probe card. After the testing, the substrate is sawed to singular the package into individual units. Then, the packages are respectively picked and placed the package on the tray or tape and reel.

Although preferred embodiments of the present invention have been described, it will be understood by those skilled in the art that the present invention should not be limited to the described preferred embodiments. Rather, various changes and modifications can be made within the spirit and scope of the present invention, as defined by the following Claims.

What is claimed is:

1. A structure of multi-chips package, comprising:
a substrate with a die receiving cavity pre-formed within said substrate;
a first die disposed within said die receiving cavity by adhesion;
a first dielectric layer formed on said first die and said substrate and filled into a gap between said first die and said substrate to absorb thermal mechanical stress there between;
a build up layer formed on said first dielectric layer, wherein said build up layer comprising a first re-distribution layer (RDL), a dielectric layer and several openings are formed on the top surface of said build up layers to expose at least one of said RDL;
conductive metals are formed on said openings and electrically coupled to said first die through said RDL;
a second die with second RDL and metal pads set up on said conductive metals with flip chip structure and surrounds by a core paste with several open through holes formed therein, wherein said first die and said second die keep electrical contact through said conductive metals;
a contact metal filled said open through holes for electrically coupling to said first die and said second die.

2. The structure of claim 1, further comprising a build up layer formed on said core paste, wherein said build up layer comprising a third re-distribution layer (RDL) and a dielectric layer and several openings on the top surface of said build up layers to expose at least one of said RDL.

3. The structure of claim 2, further comprising the solder conductive metal on the opening of the third RDL.

4. The structure of claim 1, wherein the material of said first dielectric layer is elastic material.

5. The structure of claim 4, wherein said first dielectric layer comprise a silicone dielectric based material, BCB or PI, wherein said silicone dielectric based material comprises siloxane polymers (SINR), Dow Corning WL5000 series, or combination thereof.

6. The structure of claim 1, wherein the material of said substrate includes epoxy type FR5, FR4, BT, PCB (print circuit board), alloy, glass, silicon, ceramic or metal.

7. The structure of claim 1, wherein said dielectric layer comprise a photosensitive (photo patternable) layer.

8. The structure of claim 1, wherein said RDL is made from an alloy comprising Ti/Cu/Au alloy or Ti/Cu/Ni/Au alloy.

9. The structure of claim 1, wherein said first RDL fans out from said first die.

10. The structure of claim 1, wherein the CTE of said RDL is the same as that of said substrate.

11. A method for forming multi-chips package comprising:
providing a substrate with a pre-formed die receiving cavity and metal pads on an upper surface of said substrate;
re-distribute a first die on a die redistribution tool with desired pitch by a pick and place fine alignment system, and an adhesive material applied at the periphery area of said carrier tool to adhere said substrate;
attaching an adhesive material on back side of said die;
bonding said die to said cavity of said substrate, and then performing curing to ensure said die is attached on said substrate;
separating said die redistribution tool from said substrate;
coating a first dielectric layer on said die and said substrate, and filling said dielectric layer into the gap between said die and said cavity;
performing vacuum procedure to eliminate bubble;
forming build up layers, wherein said build up layer comprising a first RDL and a second dielectric layer;
forming several openings on the top surface of said build up layers to expose at least one of said first RDL;
forming conductive metals on said openings;
setting up a second die with a second RDL and metal pads on said conductive metals;
forming a layer of core paste surrounding said second die, wherein certain open through holes are formed in said core paste for exposing said RDL and;
Filling said open through holes by conductive metal;
forming a third RDL and conductive pads over said core paste;
forming a protection layer over said core paste with openings for exposing said conductive pads and conductive metal.

12. The method of claim 11, utilizing photo mask process for forming said openings.

13. The method of claim 11, wherein said dielectric layer comprise a silicone dielectric based material, BCB or PI, wherein said silicone dielectric based material comprises siloxane polymers (SINR), Dow Corning WL5000 series, or combination thereof.

14. The method of claim 11, wherein the material of said substrate includes epoxy type FR5, FR4, BT, PCB (print circuit board), alloy, glass, silicon, ceramic or metal.

15. The method of claim 11, wherein said dielectric layer comprise a photosensitive (photo patternable) layer.

16. The method of claim 11, wherein said RDL is made from an alloy comprising Ti/Cu/Au alloy or Ti/Cu/Ni/Au alloy.

17. The method of claim 11, wherein said first RDL fans out from said first die.
